(19) United States
(12) Patent Application Publication
(10) Pub. No.: US 2024/0097071 A1
(43) Pub. Date: Mar. 21, 2024

(54) DISPLAY SUBSTRATE, PREPARATION METHOD THEREFOR, AND DISPLAY DEVICE

(71) Applicant: BOE Technology Group Co., Ltd., Beijing (CN)

(72) Inventors: Xinhong LU, Beijing (CN); Xiaoyan ZHU, Beijing (CN); Qi QI, Beijing (CN); Hao CHEN, Beijing (CN)

(21) Appl. No.: 18/262,802

(22) PCT Filed: Jan. 25, 2021
(86) PCT No.: PCT/CN2021/073657

§ 371 Date: Jul. 25, 2023

(51) Int. Cl. H01L 33/24; H01L 25/075; H01L 33/62

(52) U.S. Cl. CPC H01L 33/24; H01L 25/0753; H01L 33/62

(57) ABSTRACT

Disclosed in the present application are a display substrate, a preparation method therefor, and a display device. The display substrate includes a rigid substrate, and a flexible film layer and a display function layer that are sequentially stacked on the rigid substrate. The rigid substrate is provided with an opening at a bending region to expose the flexible film layer in the bending region. The display substrate further includes a first light absorption portion in a display region and is on the side of the display region close to the bending region. The first light absorption portion is on the side of the rigid substrate facing away from the flexible film layer or is between the rigid substrate and the flexible film layer.

### CROSS REFERENCE TO RELATED APPLICATIONS

The present disclosure is a US National Stage of International Application No. PCT/CN2021/073657, filed on Jan. 25, 2021, the entire contents of which are incorporated herein by reference.

### FIELD

The present application relates to the technical field of display, in particular to a display substrate, a preparation method therefor and a display apparatus.

### BACKGROUND

As a new generation of display technology, a micro/mini light emitting diode (Micro/Mini-LED) display technology has the advantages of high brightness, good light-emitting efficiency, low power consumption and the like. Generally, a Micro/Mini-LED chip is transfer-printed to a display substrate through a transfer-printing technology, and due to limitations of the transfer-printing technology, a large-size LED display substrate cannot be directly prepared. Therefore, a plurality of small-size LED display substrates are generally spliced to form the large-size LED display substrate.

The small-size LED display substrate generally includes a display region and a bonding region, the display region is used for display, and the bonding region is used for being bonded with a flexible circuit board, such that an external signal may be written into the display substrate through the flexible circuit board. In the related art, a bending region is further arranged between the display region and the bonding region on the small-size LED display substrate, such that a part of the bonding region can be bent to a back of the display substrate. During splicing, a spacing between the display regions in the adjacent small-size LED display substrates can be greatly reduced, so that a splicing gap can be reduced. However, an existing LED display substrate is not easy to bend due to a complex structure and a large thickness of a film layer in the bending region.

### SUMMARY

In view of this, embodiments of the present application provide a display substrate, a preparation method therefor, and a display apparatus, and a specific solution is as follows.

In a first aspect, an embodiment of the present application provides a display substrate, including: a display region, a bending region and a bonding region, wherein the display substrate is bent along the bending region, such that the bending region is bent on a backlight side of the display region of the display substrate; the display substrate includes a rigid substrate, and a flexible film layer and a display function layer that are sequentially stacked on the rigid substrate; the rigid substrate has an opening in the bending region so as to expose the flexible film layer in the bending region; the display substrate further includes: a first light absorption portion in the display region and on one side of the display region close to the bending region; and the first light absorption portion is on one side of the rigid substrate facing away from the flexible film layer or on one side of the rigid substrate facing the flexible film layer.

Optionally, in the present application, the display substrate further includes: a second light absorption portion in the bonding region and on one side of the bonding region close to the bending region; and the second light absorption portion is on the side of the rigid substrate facing away from the flexible film layer or on the side of the rigid substrate facing the flexible film layer.

Optionally, in the present application, a material of the first light absorption portion includes an inorganic material; and/or a material of the second light absorption portion includes an inorganic material.

Optionally, in the present application, a boundary of one side of the first light absorption portion close to the bending region and a boundary of the side of the display region close to the bending region have a preset distance therebetween.

Optionally, in the present application, a width of a light absorption layer is greater than or equal to 1 mm.

Optionally, in the present application, the inorganic material includes a semiconductor material, and a band gap Eg of the semiconductor material meets the following conditions:

Eg≤hkc/λ;
wherein λ is a wavelength of laser light used when a laser lift-off technology is used to form the opening, h is a Planck constant, k is a constant, and c is a speed of light.

Optionally, in the present application, the semiconductor material includes a metal oxide semiconductor or a silicon semiconductor.

Optionally, in the present application, the silicon semiconductor includes polycrystalline silicon or monocrystalline silicon.

Optionally, in the present application, a thickness of the first light absorption portion is 300 angstroms to 3000 angstroms; and a thickness of the second light absorption portion is 300 angstroms to 3000 angstroms.

Optionally, in the present application, the first light absorption portion is arranged to be the same as the second light absorption portion in layer and material.

Optionally, in the present application, the first light absorption portion and the second light absorption portion are both arranged on one side of the rigid substrate facing the flexible film layer.

Optionally, in the present application, the rigid substrate includes a first sub-rigid substrate and a second sub-rigid substrate, the first sub-rigid substrate is at the display region, and the second sub-rigid substrate is at the bonding region; and the display substrate further includes: a first buffer adhesive covering a side wall of the first sub-rigid substrate facing the opening.

Optionally, in the present application, the display substrate further includes: a second buffer adhesive covering a side wall of the second sub-rigid substrate facing the opening.

Optionally, in the present application, the display function layer includes: a buffer layer on one side of the flexible film layer away from the rigid substrate; a plurality of first wires on one side of the buffer layer away from the flexible film layer; a first insulating layer on sides of the first wires away from the flexible film layer; a plurality of second wires on one side of the first insulating layer away from the flexible film layer, wherein each first wire is connected with at least one second wire through a first via hole penetrating through the first insulating layer; a second insulating layer on sides of the second wires away from the flexible film layer; and a light emitting diode on one side of the second insulating layer away from the flexible film layer, wherein the light emitting diode is connected with the second wires through a second via hole penetrating through the second insulating layer.

In a second aspect, the present application further provides a display apparatus, including a plurality of display substrates spliced together provided by this embodiment of the present application.

In a third aspect, the present application further provides a method for preparing a display substrate, wherein the display substrate includes a display region, a bending region and a bonding region, and the bending region is between the display region and the bonding region; and the method includes: forming a flexible film layer on a first surface of a rigid substrate; forming a display function layer on one side of the flexible film layer away from the rigid substrate; removing the rigid substrate in the bending region by adopting a laser lift-off process from one side of a second surface of the rigid substrate; and bending the display substrate in the bending region, such that the display function layer in the bonding region and the display function layer in the display region are on different surfaces of the display substrate; the method further includes: forming a first light absorption portion on the first surface of the rigid substrate before forming the flexible film layer on the first surface of the rigid substrate; or, forming the first light absorption portion on the second surface of the rigid substrate before forming the flexible film layer on the first surface of the rigid substrate; or, forming the first light absorption portion on the second surface of the rigid substrate after forming the display function layer and before removing the rigid substrate of the bending region by adopting the laser lift-off process; wherein the first light absorbing portion is in the display region and on one side of the display region close to the bending region, and the first light absorption portion is configured to absorb light including a waveband of a laser light.

In a possible implementation, the preparation method further includes: forming a second light absorption portion on the first surface of the rigid substrate before forming the flexible film layer on the first surface of the rigid substrate; or, forming the second light absorption portion on the second surface of the rigid substrate before forming the flexible film layer on the first surface of the rigid substrate; or, forming the second light absorption portion on the second surface of the rigid substrate after forming the display function layer and before removing the rigid substrate of the bending region by adopting the laser lift-off process; wherein the second light absorbing portion is in the bonding region and on one side of the bonding region close to the bending region, and the second light absorption portion is configured to absorb light including a waveband of a laser light.

In a possible implementation, the first light absorption portion and the second light absorption portion are formed at the same time.

### BRIEF DESCRIPTION OF THE DRAWINGS

FIG. 1 is a schematic structural diagram of a display substrate in the related art.

FIG. 2 is a schematic structural diagram of abnormal display of a display substrate in the related art.

FIG. 3 is a schematic structural diagram of a display substrate provided by an embodiment of the present application before bending.

FIG. 4 is another schematic structural diagram of a display substrate provided by an embodiment of the present application before bending.

FIG. 5 is a schematic diagram of laser lift-off of a display substrate provided by an embodiment of the present application.

FIG. 6 is yet another schematic structural diagram of a display substrate provided by an embodiment of the present application before bending.

FIG. 7 is yet another schematic structural diagram of a display substrate provided by an embodiment of the present application before bending.

FIG. 8 is a partial schematic structural diagram of a display substrate provided by an embodiment of the present application.

FIG. 9 is a partial schematic structural diagram of a display substrate provided by an embodiment of the present application.

FIG. 10 is a schematic structural diagram of a display substrate provided by an embodiment of the present application after bending.

FIG. 11 is another schematic structural diagram of a display substrate provided by an embodiment of the present application after bending.

FIG. 12 is yet another schematic structural diagram of a display substrate provided by an embodiment of the present application before bending.

FIG. 13 is yet another schematic structural diagram of a display substrate provided by an embodiment of the present application after bending.

FIG. 14 is a schematic flowchart of a preparation method of a display substrate provided by an embodiment of the present application.

FIG. 15 is another schematic flowchart of a preparation method of a display substrate provided by an embodiment of the present application.

### DETAILED DESCRIPTION OF THE EMBODIMENTS

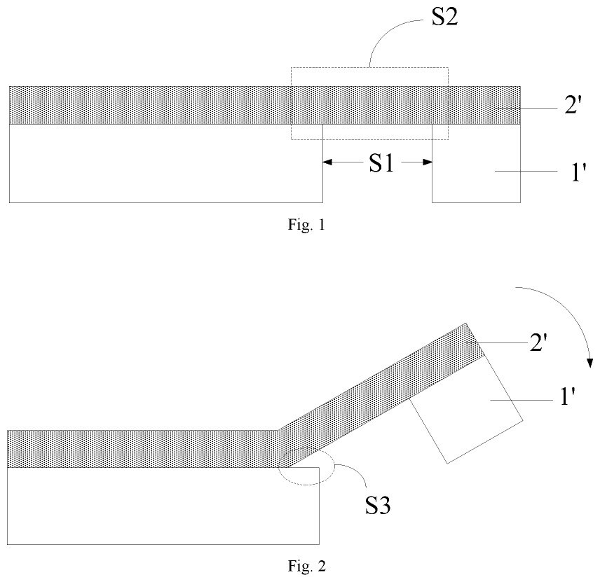

In a solution of the related art, when preparing a display substrate for splicing, it is necessary to remove a rigid substrate of a bending region of the display substrate, so as to bend a region other than a display region to a back of the display substrate. When removing the rigid substrate of the bending region, laser lift-off (LLO) is performed first, a chemical bond between the rigid substrate and the flexible substrate is broken through laser light, so that the rigid substrate in the bending region is separated from a flexible substrate, and then the rigid substrate of the bending region is cut off by cutting the rigid substrate. Since general LLO devices do not have a precise alignment function, a lift-off position is not controllable in an actual process. In order to ensure that the rigid substrate in the bending region can be completely lifted off, a laser action region can only be expanded, so that the laser action region will exceed the bending region. As shown in FIG. 1, S1 is a bending region, a rigid substrate 1′ in the region S1 is needed to be separated from a flexible substrate 2′ through an LLO technology. However, due to a poor accuracy of the laser light, a flexible substrate 2′ in a region S2 will be separated from the rigid substrate 1′. It can be seen from FIG. 1, an area of the region S2 is greater than an area of the region S1, that is, the flexible substrate 2′ in a junction of the display region and the bending region and a junction of the bonding region and the bending region will be separated from the rigid substrate 1′. As shown in FIG. 2, when the display substrate is bent in the bending region, a buffer adhesive between the rigid substrate 1′ and the flexible substrate 2′ which are located in a region S3 will overflow, resulting in a large difference between a height of this region and a height of other regions of the display region, which will increase the height of the region S3 by 70-80 μm, and appearance of the display substrate and a display effect of a large viewing angle are affected.

In order to solve the above problems, embodiments of the present application provide a display substrate, a preparation method therefor, and a display apparatus, to avoid abnormal display.

In order to make the objectives, features and advantages of the present application more obvious and understandable, the present application will be further described below in combination with accompanying drawings and embodiments. However, example implementations can be implemented in a variety of forms and should not be construed as limited to the implementations set forth herein; and on the contrary, providing these implementations makes the present application more comprehensive and complete, and comprehensively communicates the concept of the example implementations to those skilled in the art. In the figures, the same reference numerals represent the same or similar structures, so their repeated description will be omitted. The words expressing positions and directions described in the present application are illustrated by taking the accompanying drawings as an example, but they can also be changed as needed, and all the changes are included in the protection scope of the present application. The accompanying drawings of the present application are only used to illustrate a relative positional relationship and do not represent the true scale.

It should be noted that specific details are described in the following description to fully understand the present application. However, the present application can be implemented in a variety of other ways different from those described herein, and those skilled in the art may make similar promotion without violating the connotation of the present application. Therefore, the present application is not subject to the specific implementations disclosed below. The subsequent description of the specification is a preferable implementation to implement the present application. However, the description is for the purpose of explaining general principles of the present application and is not intended to limit the scope of the present application. It is intended that the protection scope of the present application is only limited by the appended claims.

In combination with the accompanying drawings, the display substrate, the preparation method therefor, and the display apparatus provided by embodiments of the present application are illustrated in detail below.

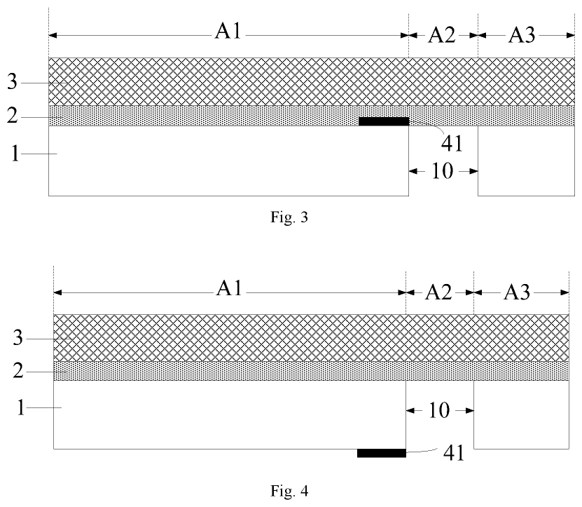

Referring to FIG. 3 and FIG. 4, FIG. 3 and FIG. 4 are schematic structural diagrams of a display substrate provided by an embodiment of the present application respectively. The display substrate provided by the embodiment of the present application includes: a display region A1, a bending region A2 and a bonding region A3, and the bending region A2 is between the display region A1 and the bonding region A3; and the display substrate is bent along the bending region A2, such that the bending region A2 is bent on a backlight side of the display region A1 of the display substrate. FIG. 3 and FIG. 4 are schematic structural diagrams corresponding to the display substrate before bending.

Continue to refer to FIG. 3 and FIG. 4, the display substrate includes a rigid substrate 1, as well as a flexible film layer 2 and a display function layer 3 that are sequentially stacked on the rigid substrate 1; the rigid substrate 1 has an opening 10 which is formed by using a laser lift-off process at the bending region A2 so as to expose the flexible film layer 2 in the bending region A2. The rigid substrate 1 may be a glass substrate or a quartz substrate. The flexible film layer 2 may adopt polyimide, and a thickness of the flexible film layer 2 does not exceed 6 μm, so that a bending performance of the flexible film layer 2 is better.

The display substrate may further include a first light absorption portion 41 in the display region A1 and on one side of the display region A1 close to the bending region A2. As shown in FIG. 4, the first light absorption portion 41 may be arranged on one side of the rigid substrate 1 facing away from the flexible film layer 2; or as shown in FIG. 3, the first light absorption portion 41 may be arranged on one side of the rigid substrate 1 facing the flexible film layer 2.

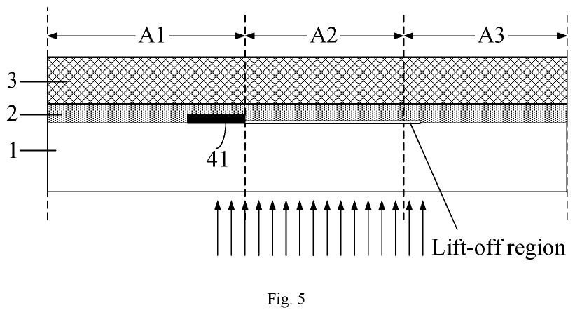

According to the display substrate provided by the embodiment of the present application, during forming, the opening 10 of the rigid substrate 1 is formed by using the laser lift-off process. Referring to FIG. 5, when the rigid substrate 1 is lifted off the flexible film layer 2 by an LLO device, a laser action region is greater than the bending region A2, so as to ensure that the rigid substrate 1 in the bending region A2 can be completely lifted off, and then the rigid substrate 1 in the bending region A2 is cut to form the opening. In the present application, because the first light absorption portion 41 is arranged on the side of the display region A1 close to the bending region A2, the first light absorption portion 41 may absorb laser light acting on the display region A1, so that the rigid substrate 1 in the display region A1 is prevented from being separated from the flexible film layer 2.

In the embodiment of the present application, because the first light absorption portion is arranged, the laser light used by LLO does not need high-precision alignment. Even if a portion of energy of the laser light exceeds the bending region, the energy may also be absorbed by the first light absorption portion.

It needs to be illustrated that in the present application, at a boundary of the first light absorption portion close to the bending region, due to a diffraction phenomenon, there may be a lift-off region of about 10 μm at the boundary of the first light absorption portion. Of course, when wavelength of ultraviolet light is different, the boundary deviation caused by this diffraction will be slightly different. Specifically, in combination with a boundary alignment accuracy (±20 μm) of the first light absorption portion, in theory, a maximum deviation of the lift-off region from the bending region does not exceed 20 μm.

During specific implementation, considering the alignment accuracy of the LLO device, a linewidth of the first light absorption portion needs to be set to be greater than the alignment accuracy of the LLO device. Since conventional LLO does not have an alignment function, and only a mechanical position accuracy during placing is about 1 mm, the linewidth of the first light absorption portion may be greater than 1 mm. The first light absorption portion is arranged at a boundary of the display region and the bending region, and an edge of the first light absorption portion may coincide with an edge of the bending region.

In the present application, since the first light absorption portion is arranged on the backlight side of the display function layer and may not affect display, the first light absorption portion may be arranged to cover the display region.

In the present application, in order to realize bending of the display substrate, the flexible film layer may be only arranged at the bending region, of course, the flexible film layer may also be arranged on a whole layer, that is, the flexible film layer covers the rigid substrate and the opening of the rigid substrate, which is not limited herein. The following embodiments of the present application take the flexible film layer being arranged on the whole layer as an example for illustration.

During specific implementation, when film layers are both formed on two sides of the rigid substrate, the rigid substrate needs to be turned over during preparation, which will increase process difficulty. Therefore, in the present application, the first light absorption portion is preferably arranged between the rigid substrate and the flexible film layer.

Exemplarily, in the present application, a material of the first light absorption portion may include an inorganic material and/or an organic material. When the material of the first light absorption portion is the organic material, on the one hand, the organic material may harden when absorption light is strong during laser lift-off, on the other hand, a decomposition reaction may occur, causing the first light absorption portion to overflow in a direction of the bending region, thereby affecting a boundary definition accuracy of the first light absorption portion. Therefore, the material of the first light absorption portion is the inorganic material preferably.

During specific implementation, the wavelength of the laser light used in the laser lift-off process may be 280-308 nm, and the material of the first light absorption portion may be selected as the inorganic material that can absorb the laser light in this waveband.

Optionally, in the present application, the material of the first light absorption portion may include a semiconductor material, and a band gap Eg of the semiconductor material meets the following conditions:

Eg≤hkc/λ; and
λ is the wavelength of the laser light used when a laser lift-off technology is used to form the opening of the rigid substrate; h is a Planck constant, its value is 6.626*10⁻³⁴ J·s; k is a constant, its value is 1.6*10⁻¹⁹ J/eV; c is a speed of light, and its value is 3*10⁸ m/s=3*10¹⁷ nm/s.

Therefore, in the present application, the band gap Eg of the semiconductor material needs to meet: Eg≤1240/λ eV, the semiconductor materials within this band gap range may all absorb the laser light in a form of its own electron-excited transition. Taking laser wavelength λ=308 nm as an example, the band gap Eg of the semiconductor material is ≤4.02 eV.

Exemplarily, in the present application, the semiconductor material may include a metal oxide semiconductor or a silicon semiconductor.

For example, the metal oxide semiconductor meeting Eg≤4.02 eV may include zinc oxide (ZnO), titanium oxide (TiO₂), copper oxide (CuO), iron oxide (Fe₂O₃), indium oxide (In₂O₃), vanadium oxide (V₂O₅) or the like, which is not limited herein.

During specific implementation, since the band gap Eg of the polycrystalline silicon (p-Si) and the monocrystalline silicon (a-Si) satisfies Eg≤2 eV, in the present application, the silicon semiconductor may include the polycrystalline silicon (p-Si) or the monocrystalline silicon (a-Si).

In addition, when the material of the first light absorption portion is the p-Si or the a-Si, the p-Si or the a-Si is the material commonly used in the field of display, so it may be formed by using an existing device during preparation. During specific implementation, the existing device and process are adopted, a film layer thickness of the p-Si or the a-Si can reach 300-3000 angstroms (Å). Therefore, in the present application, the thickness of the first light absorption portion may be controlled to be 300-3000 angstroms (Å), such as 300 Å, 1000 Å and 2500 Å, which is not limited herein.

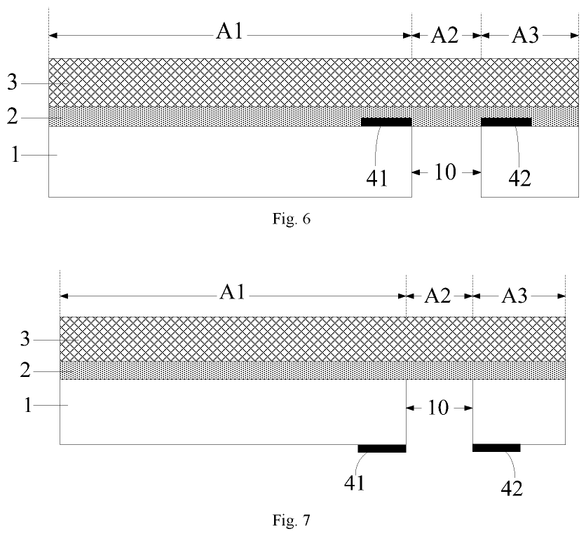

Further, in the present application, the bonding region is close to one side of the bending region, since the laser action region may exceed the bonding region, there will also be a situation of lift-off between the rigid substrate and the flexible film layer in the bonding region, which may reduce mechanical rigidity of the bonding region subsequently. Therefore, in the present application, as shown in FIG. 6 and FIG. 7, the display substrate further includes a second light absorption portion 42 in the display region A1 and on one side of the bonding region A3 close to the bending region A2, and the second light absorption portion 42 is configured to absorb light including the waveband of the laser light.

As shown in FIG. 6, the second light absorption portion is on one side of the rigid substrate 1 facing away from the flexible film layer 2, or as shown in FIG. 7, the second light absorption portion is between the rigid substrate 1 and the flexible film layer 2. In this way, the rigid substrate 1 of the bending region may be prevented from being lifted off the flexible film layer 2.

It needs to be illustrated that in the present application, at a boundary of the second light absorption portion close to the bending region, due to a diffraction phenomenon, there may be a lift-off region of about 10 μm at the boundary of the second light absorption portion. Of course, when wavelength of ultraviolet light is different, the boundary deviation caused by this diffraction will be slightly different. Specifically, in combination with a boundary alignment accuracy (±20 μm) of the second light absorption portion, in theory, a maximum deviation of the lift-off region from the bending region does not exceed 20 μm.

During specific implementation, considering the alignment accuracy of the LLO device, a linewidth of the second light absorption portion needs to be set to be greater than the alignment accuracy of the LLO device. Since conventional LLO does not have an alignment function, and only a mechanical position accuracy during placing is ±1 mm, the linewidth of the second light absorption portion may be greater than 1 mm. The first light absorption portion is arranged at a boundary of the bonding region and the bending region, and an edge of the second light absorption portion may coincide with an edge of the bending region.

In the present application, since the second light absorption portion is arranged on the backlight side of the display function layer and may not affect display, the second light absorption portion may be arranged to cover the display region.

During specific implementation, when film layers are both formed on two sides of the rigid substrate, the rigid substrate needs to be turned over during preparation, which will increase process difficulty. Therefore, in the present application, the second light absorption portion is preferably arranged between the rigid substrate and the flexible film layer.

Exemplarily, in the present application, a material of the second light absorption portion may include an inorganic material, and/or an organic material. When the material of the second light absorption portion is the organic material, on the one hand, the organic material may harden when absorption light is strong during laser lift-off, on the other hand, a decomposition reaction may occur, causing the second light absorption portion to overflow in a direction of the bending region, thereby affecting a boundary definition accuracy of the second light absorption portion. Therefore, the material of the first light absorption portion is the inorganic material preferably.

During specific implementation, the wavelength of the laser light used in the laser lift-off process may be 280-308 nm, and the material of the second light absorption portion may be selected as the inorganic material that can absorb the laser light in this waveband.

Optionally, in the present application, the material of the second light absorption portion may include a semiconductor material, and a band gap Eg of the semiconductor material meets the following conditions:

Eg≤hkc/λ; and
λ is the wavelength of the laser light, h is a Planck constant, its value is 6.626*10⁻³⁴ J·s; k is a constant, its value is 1.6*10⁻¹⁹ J/eV; c is a speed of light, and its value is 3*10⁸ m/s=3*10¹⁷ nm/s.

Exemplarily, in the present application, the semiconductor material may include a metal oxide semiconductor or a silicon semiconductor.

For example, the metal oxide semiconductor meeting Eg≤4.02 eV may include zinc oxide (ZnO), titanium oxide (TiO₂), copper oxide (CuO), iron oxide (Fe₂O₃), indium oxide (In₂O₃), vanadium oxide (V₂O₅) or the like, which is not limited herein.

During specific implementation, since the band gap Eg of the polycrystalline silicon (p-Si) and the monocrystalline silicon (a-Si) satisfies Eg≤2 eV, in the present application, the silicon semiconductor may include the polycrystalline silicon (p-Si) or the monocrystalline silicon (a-Si).

In addition, when the material of the second light absorption portion is the p-Si or the a-Si, the p-Si or the a-Si is the material commonly used in the field of display, so it may be formed by using a later device during preparation. During specific implementation, the existing device and process are adopted, a film layer thickness of the p-Si or the a-Si can reach 300-3000 angstroms (Å). Therefore, in the present application, the thickness of the second light absorption portion may be controlled to be 300-3000 angstroms (Å), such as 300 Å, 1000 Å and 2500 Å, which is not limited herein.

In order to simplify the process, the first light absorption portion is arranged to be the same as the second light absorption portion in layer and material. In this way, patterns of the first light absorption portion and the second light absorption portion may be formed at the same time by using a one-time patterning process, so that a cost may be reduced.

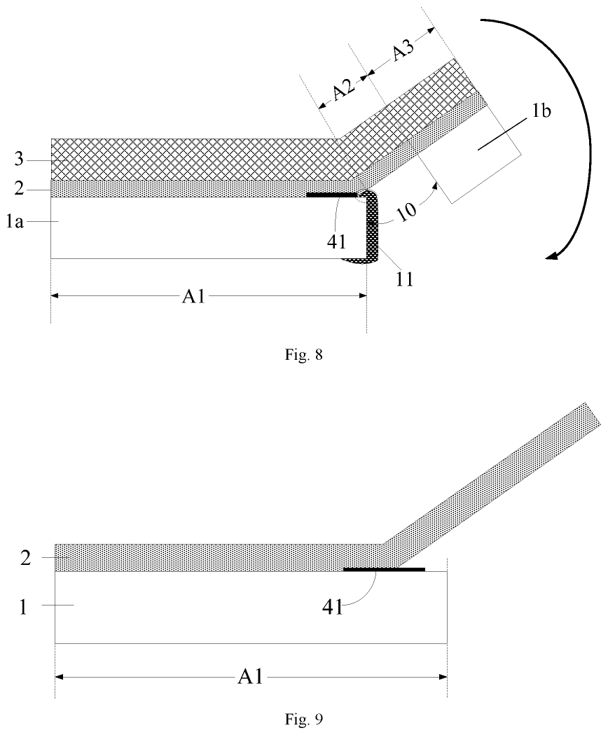

Further, as shown in FIG. 8, the rigid substrate 1 includes a first sub-rigid substrate 1a and a second sub-rigid substrate 1b. The first sub-rigid substrate 1a is arranged in the display region A1, and the second sub-rigid substrate 1b is arranged in the bonding region A3. The display substrate further includes: a first buffer adhesive 11 covering a side wall of the first sub-rigid substrate 1a facing the opening. The first buffer adhesive 11 may avoid a situation that: when the flexible film layer 2 is bent, a bending angle of the bending region is too large, resulting in breaking of the bending region.

Further, the display substrate of the present application further includes a second buffer adhesive covering a side wall of the second sub-rigid substrate facing the opening.

In the present application, when the first buffer adhesive 11 is arranged at the opening 10 of the rigid substrate 1, a position of the first buffer adhesive 11 is at a position shown in a circle, then as a bending process proceeds, the first buffer adhesive 11 slowly overflows until it covers the backlight side of the rigid substrate 1, and if the first light absorption portion 41 arranged on the side of the rigid substrate 1 facing away from the flexible film layer 2 is too thick, it will prevent the first buffer adhesive 11 from flowing to a bottom side of the rigid substrate 1, resulting in that the first buffer adhesive 11 is blocked and cannot flow out after bending.

Therefore, optionally, in the present application, the first light absorption portion 41 and the second light absorption portion 42 are both arranged between the flexible film layer 2 and the rigid substrate 1. Alternatively, when the first light absorption portion 41 and the second light absorption portion 42 are both arranged on the side of the rigid substrate 1 facing away from the flexible film layer 2, the thicknesses of the first light absorption portion 41 and the second light absorption portion 42 should not be too large.

Further, in the present application, in order to effectively protect the buffer adhesive at a corner of the bending region, the buffer adhesive may overflow some to the display region, so that the lift-off region of the rigid substrate and the flexible film layer needs to be capable of extending some into the display region, which requires the first light absorption portion to shrink into the display region by a preset distance, that is, a boundary of the first light absorption portion close to the bending region and a boundary of the display region close to the bending region have the preset distance therebetween.

In combination with the boundary alignment accuracy (±20 μm) of the first light absorption portion, in theory, a maximum deviation of the lift-off region from the bending region does not exceed 20 μm. Considering a diffraction effect at the boundary of the first light absorption portion, a distance of shrinking into the display region from the first light absorption portion is less than 20 μm. Referring to FIG. 9, for example, the diffraction effect at the boundary of the first light absorption portion 41 can lead to a lift-off region of 10 μm, and then, a distance S1 of shrinking into the display region A1 from the first light absorption portion 41 may be set as 10 μm.

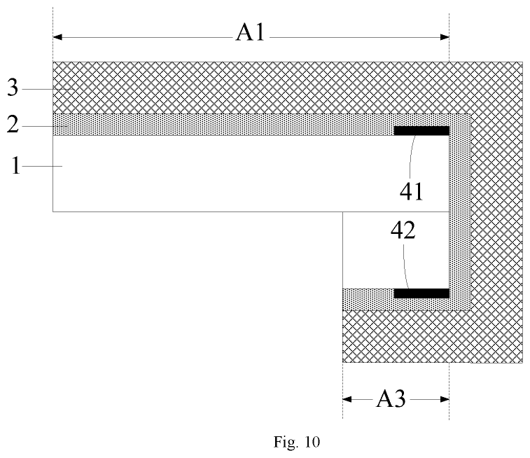

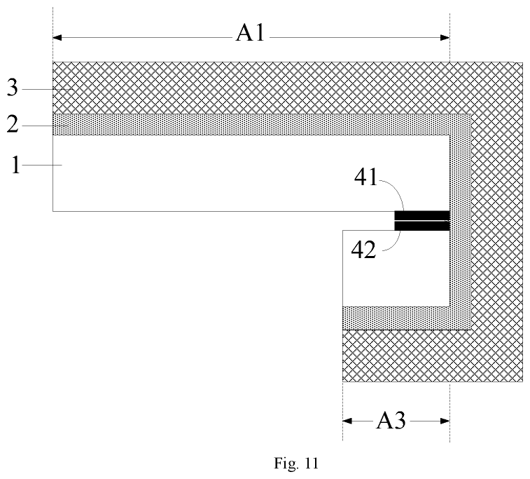

Specifically, in the present application, referring to FIG. 10 and FIG. 11, after the display substrate is bent, the display function layer 3 in the display region A1 and the display function layer 3 in the bonding region A3 are arranged on different surfaces of the display substrate respectively, the display function layer 3 in the display region A1 is arranged on a light emitting side of the display substrate, and the display function layer 3 in the bonding region A3 is arranged on the backlight side of the display substrate.

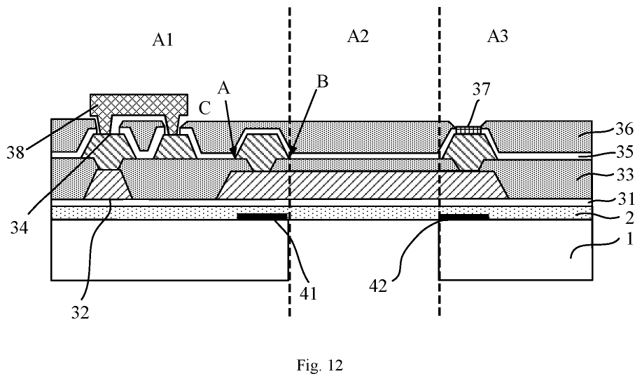

During specific implementation, in the present application, referring to FIG. 12, the display function layer may include:
a buffer layer 31 on one side of the flexible film layer 2 away from the rigid substrate 1, wherein the buffer layer 31 may adopt one or more insulating materials of silicon nitride, silicon oxide and silicon oxynitride;
a plurality of first wires 32 on one side of the buffer layer 31 away from the flexible film layer 2, wherein the first wires 32 may adopt Cu, and a thickness is 0.6-1.8 μm;
a first insulating layer 33 on one sides of the first wires 32 away from the flexible film layer 2, wherein the first insulating layer 33 may include a first flat layer, the first flat layer may adopt an organic insulating material with a large thickness, such as organic resin, to fill gaps among the first wires 32, a flat surface is provided for the subsequent process, a large segment difference is avoided in the subsequent process, so that LED displacement will not occur during LED bonding, a thickness of the first flat layer should be greater than or equal to the thickness of the first wire, and the thickness of the first flat layer may be 2-3.5 μm; in addition to the first flat layer, the first insulating layer may further include an inorganic insulating layer, the inorganic insulating layer may adopt inorganic insulating materials such as silicon nitride, silicon oxide and silicon oxynitride, to protect the first wires against oxidation in a subsequent high-temperature process, and a thickness of the inorganic insulating layer may be 500-3000 angstroms;
a plurality of second wires 34 on one side of the first insulating layer 33 away from the flexible film layer 2, wherein each first wire 32 is connected with at least one second wire 34 through a first via hole penetrating through the first insulating layer 33; and the second wires 34 may adopt Cu, and a thickness is 0.6-1.2 μm;
a second insulating layer on one sides of the second wires 34 away from the flexible film layer 2, wherein the second insulating layer may include a passivation layer 35 and a second flat layer 36, the passivation layer 35 may adopt inorganic insulating materials such as silicon nitride, silicon oxide and silicon oxynitride, to protect the second wires against oxidation in a subsequent high-temperature process, and a thickness of the passivation layer 35 may be 500-3000 angstroms; the second flat layer 36 may adopt an organic insulating material with a large thickness, such as organic resin, to fill gaps among the second wires, a flat surface is provided for the subsequent process, a large segment difference is avoided in the subsequent process, so that LED displacement will not occur during LED bonding, and a thickness of the second flat layer 36 should be greater than or equal to the thickness of the second wires; and
a light emitting diode LED38 on one side of the second insulating layer away from the flexible film layer 2, and the LED38 is connected with the second wires 34 through a second via hole penetrating through the second insulating layer. Specifically, the LED38 may be formed on the display substrate through printing soldering, crystal solidification, reflow soldering, packaging and other processes. The LED38 includes N pad and P pad, and the N pad and P pad of the LED are connected with the second wires 34 at different positions through the second via hole penetrating through the second flat layer 36 and the passivation layer 35 respectively.

During specific implementation, as shown in FIG. 12, in order to protect the exposed second wires 34 against oxidation, a conductive protective layer 37 may further be formed on the second wires 34, and the conductive protective layer 37 may adopt ITO.

During specific implementation, a boundary between the bending region A2 and the display region A1 in the display substrate is generally defined by a boundary of the second wires, as shown in FIG. 12, the boundary B of the second wires 34 is the boundary of the display region A1, wherein a point A is a left boundary of the second wire 34 arranged right above the first light absorption portion 41, a point B is a right boundary of the second wire 34 arranged right above the first light absorption portion 41, and a point C is a boundary of an outer contour of an LED chip close to the bending region.

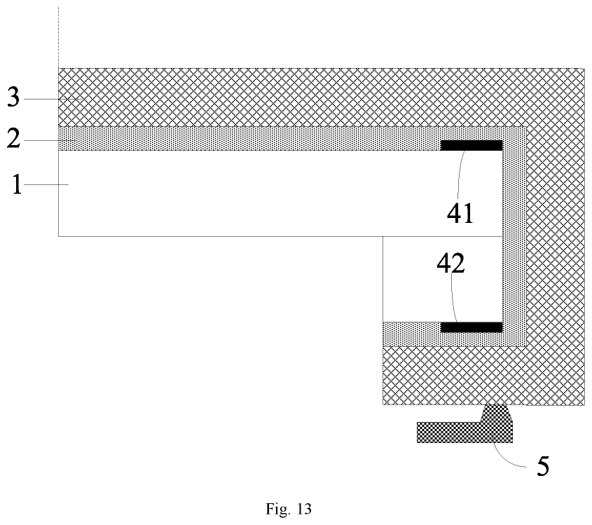

During specific implementation, as shown in FIG. 13, a flexible circuit board 5 is further bonded in the bonding region A3.

Based on the same inventive concept, the present application further provides a preparation method for any above display substrate, the display substrate includes a display region, a bending region and a bonding region, and the bending region is between the display region and the bonding region.

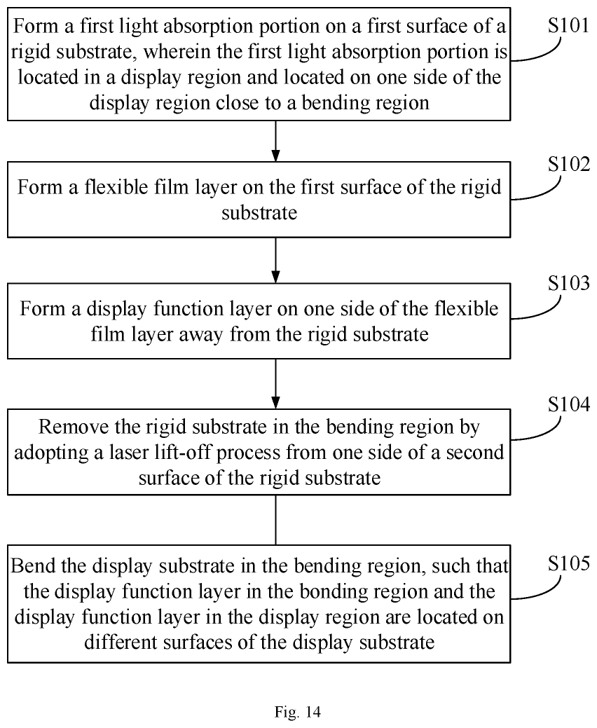

As shown in FIG. 14, the preparation method includes S101 to S105.

S101, a first light absorption portion is formed on a first surface of a rigid substrate, wherein the first light absorption portion is arranged in a display region and on one side of the display region close to a bending region.

S102, a flexible film layer is formed on the first surface of the rigid substrate.

S103, a display function layer is formed on one side of the flexible film layer away from the rigid substrate.

S104, the rigid substrate of the bending region is removed by adopting a laser lift-off process from one side of a second surface of the rigid substrate.

S105, the display substrate is bent in the bending region, such that the display function layer of the bonding region and the display function layer of the display region are arranged on different surfaces of the display substrate.

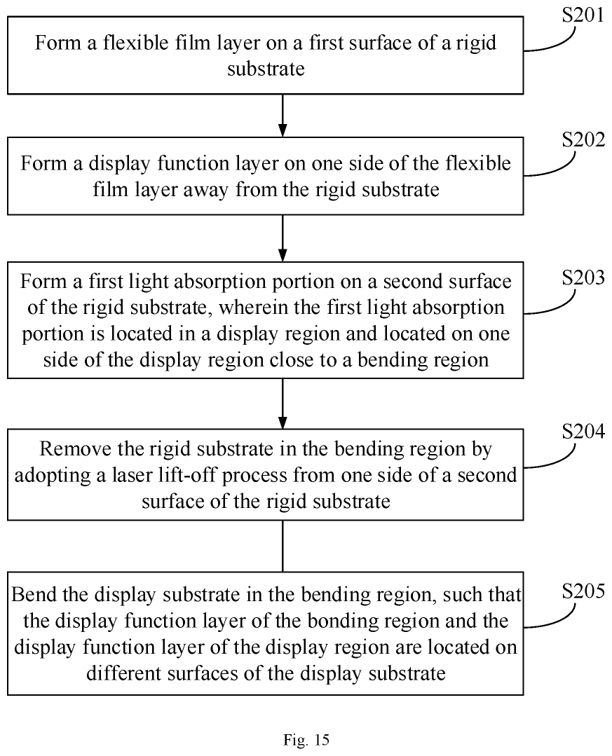

Alternatively, as shown in FIG. 15, the preparation method includes S201 to S205.

S201, a flexible film layer is formed on a first surface of a rigid substrate.

S202, a display function layer is formed on one side of the flexible film layer away from the rigid substrate.

S203, a first light absorption portion is formed on a second surface of the rigid substrate, wherein the first light absorption portion is arranged in a display region and on one side of the display region close to a bending region.

S204, the rigid substrate of the bending region is removed by adopting a laser lift-off process from one side of a second surface of the rigid substrate.

S205, the display substrate is bent in the bending region, such that the display function layer of the bonding region and the display function layer of the display region are arranged on different surfaces of the display substrate.

According to the preparation method provided by the embodiment of the present application, during forming, the rigid substrate of the bending region is lifted off by using the laser lift-off process, when the rigid substrate is lifted off the flexible film layer by using an LLO device, a laser action region is greater than the bending region, so as to ensure that the rigid substrate in the bending region can be completely lifted off, and then the rigid substrate 1 of the bending region is cut to form the opening. In the present application, because the first light absorption portion is arranged on the side of the display region close to the bending region A2, the first light absorption portion may absorb laser light acting on the display region, so that the rigid substrate of the display region is prevented from being separated from the flexible film layer.

In a feasible implementation, the preparation method further includes: a second light absorption portion is formed on the first surface of the rigid substrate before forming the flexible film layer on the first surface of the rigid substrate; and the second light absorption portion is arranged in the bonding region and arranged on one side of the bonding region close to the bending region, and the second light absorption portion is configured to absorb light including the waveband of the laser light.

Alternatively, in a feasible implementation, the preparation method further includes: a second light absorption portion is formed on the second surface of the rigid substrate after forming the display function layer and before removing the rigid substrate of the bending region by using the laser lift-off process; and the second light absorption portion is arranged in the bonding region and on one side of the bonding region close to the bending region, and the second light absorption portion is configured to absorb light including the waveband of the laser light.

In order to simplify the process and reduce the cost, in the preparation method of the present application, the first light absorption portion and the second light absorption portion are formed at the same time.

Based on the same inventive concept, the present application further provides a display apparatus, including a plurality of any LED display substrates spliced together provided by the embodiment of the present application.

The display apparatus includes but not limited to: a radio frequency unit, a network module, an audio output and input unit, a sensor, a display unit, a user input unit, an interface unit, a memory, a processor, a power supply and other components. Those skilled in the art may understand that the structure of the above display apparatus does not constitute a limitation of the display apparatus, and the display apparatus may include more or less components, or combinations of some components, or different component arrangements. In the embodiment of the present application, the display apparatus includes but not limited to a display, a mobile phone, a tablet computer, a television, a wearable electronic device, a navigation display device and the like. Implementation of the display apparatus may refer to the embodiments of the above display substrate, and repetitions are omitted here.

The display apparatus may be any product or component with a display function, such as a television, a display, a digital photo frame, a mobile phone and a tablet computer, and the display apparatus further includes a flexible circuit board, a printed circuit board and a back plate.

It needs to be noted that the various embodiments in the specification are described in a progressive manner, and the same or similar parts between the various embodiments can be referred to each other. Each embodiment focuses on contents different from other embodiments. In particular, as for the embodiment, as it basically similar to the product embodiment, the description is relatively simple. As for related parts, please refer to the partial description of the product embodiment.

Unless otherwise defined, technical or scientific terms used in the present disclosure shall have the ordinary meanings understood by those ordinarily skilled in the art to which the present disclosure pertains. The words “first”, “second” and the similar words used in the present disclosure do not indicate any order, quantity or importance, but are merely used to distinguish different components. The words “comprise” or “include” and the like indicate that an element or item appearing before such the word covers listed elements or items appearing after the word and equivalents thereof, and does not exclude other elements or items. The words “connect” or “couple” or the like are not limited to physical or mechanical connection, but may include electrical connection, whether direct or indirect. “Upper”, “lower”, “left”, “right” and the like are only used to represent relative position relationships, and the relative position relationships may also change accordingly after an absolute position of a described object is changed.

It may be understood that when an element such as a layer, film, region or substrate is called to be “above” or “below” another element, the element may be “directly” “above” or “below” another element, or there may be an intermediate element.

In the above description of the implementation, specific characteristics, structures, materials or features may be combined in an appropriate manner in any one or more embodiments or examples.

Apparently, those skilled in the art can make various modifications and variations to the present application without departing from the spirit and scope of the present application. In this way, under the condition that these modifications and variations of the present application fall within the scope of the claims of the present application and their equivalent technologies, the present application is also intended to include these modifications and variations.

1.-18. (canceled)

19. A display substrate, comprising: a display region, a bending region and a bonding region,
wherein the display substrate is bent along the bending region, such that the bending region is bent on a backlight side of the display region of the display substrate;
the display substrate comprises a rigid substrate, and a flexible film layer and a display function layer sequentially stacked on the rigid substrate;
the rigid substrate has an opening in the bending region to expose the flexible film layer in the bending region;
the display substrate further comprises a first light absorption portion in the display region and on one side of the display region close to the bending region; and
the first light absorption portion is on one side of the rigid substrate facing away from the flexible film layer or on one side of the rigid substrate facing the flexible film layer.

20. The display substrate according to claim 19, further comprising a second light absorption portion in the bonding region and on one side of the bonding region close to the bending region; and
the second light absorption portion is on the side of the rigid substrate facing away from the flexible film layer or on the side of the rigid substrate facing the flexible film layer.

21. The display substrate according to claim 20, wherein a material of the first light absorption portion comprises an inorganic material; and/or a material of the second light absorption portion comprises an inorganic material.

22. The display substrate according to claim 19, wherein a boundary of one side of the first light absorption portion close to the bending region and a boundary of the side of the display region close to the bending region have a preset distance therebetween.

23. The display substrate according to claim 19, wherein a width of a light absorption layer is greater than or equal to 1 mm.

24. The display substrate according to claim 21, wherein the inorganic material comprises a semiconductor material, and a band gap Eg of the semiconductor material meets the following conditions:
Eg≤hkc/λ;
wherein λ is a wavelength of laser light used when a laser lift-off technology is used to form the opening, h is a Planck constant, k is a constant, and c is a speed of light.

25. The display substrate according to claim 24, wherein the semiconductor material comprises a metal oxide semiconductor or a silicon semiconductor.

26. The display substrate according to claim 25, wherein the silicon semiconductor comprises polycrystalline silicon or monocrystalline silicon.

27. The display substrate according to claim 26, wherein a thickness of the first light absorption portion is 300 angstroms to 3000 angstroms; and
a thickness of the second light absorption portion is 300 angstroms to 3000 angstroms.

28. The display substrate according to claim 21, wherein the first light absorption portion is arranged to be the same as the second light absorption portion in layer and material.

29. The display substrate according to claim 28, wherein the first light absorption portion and the second light absorption portion are arranged on one side of the rigid substrate facing the flexible film layer.

30. The display substrate according to claim 19, wherein the rigid substrate comprises a first sub-rigid substrate and a second sub-rigid substrate, the first sub-rigid substrate is at the display region, and the second sub-rigid substrate is at the bonding region; and the display substrate further comprises:
a first buffer adhesive covering a side wall of the first sub-rigid substrate facing the opening.

31. The display substrate according to claim 30, further comprising:
a second buffer adhesive covering a side wall of the second sub-rigid substrate facing the opening.

32. The display substrate according to claim 19, wherein the display function layer comprises:
a buffer layer on one side of the flexible film layer away from the rigid substrate;
a plurality of first wires on one side of the buffer layer away from the flexible film layer;
a first insulating layer on one sides of the first wires away from the flexible film layer;
a plurality of second wires on one side of the first insulating layer away from the flexible film layer, wherein each first wire is connected with at least one second wire through a first via hole penetrating through the first insulating layer;
a second insulating layer on one sides of the second wires away from the flexible film layer; and
a light emitting diode on one side of the second insulating layer away from the flexible film layer, wherein the light emitting diode is connected with the second wires through a second via hole penetrating through the second insulating layer.

33. A display apparatus, comprising a plurality of display substrates spliced together, wherein each display substrate comprises: a display region, a bending region and a bonding region,
wherein the display substrate is bent along the bending region, such that the bending region is bent on a backlight side of the display region of the display substrate;
the display substrate comprises a rigid substrate, and a flexible film layer and a display function layer sequentially stacked on the rigid substrate;
the rigid substrate has an opening in the bending region to expose the flexible film layer in the bending region;
the display substrate further comprises a first light absorption portion in the display region and on one side of the display region close to the bending region; and
the first light absorption portion is on one side of the rigid substrate facing away from the flexible film layer or on one side of the rigid substrate facing the flexible film layer.

34. A method for preparing a display substrate, wherein the display substrate comprises a display region, a bending region and a bonding region, and the bending region is between the display region and the bonding region; and the method comprises:
forming a flexible film layer on a first surface of a rigid substrate;
forming a display function layer on one side of the flexible film layer away from the rigid substrate;
removing the rigid substrate in the bending region by adopting a laser lift-off process from one side of a second surface of the rigid substrate; and
bending the display substrate in the bending region, such that the display function layer of in bonding region and the display function layer in the display region are on different surfaces of the display substrate;
the method further comprises: forming a first light absorption portion on the first surface of the rigid substrate before forming the flexible film layer on the first surface of the rigid substrate;
or, forming a first light absorption portion on the second surface of the rigid substrate before forming the flexible film layer on the first surface of the rigid substrate;
or, forming a first light absorption portion on the second surface of the rigid substrate after forming the display function layer and before removing the rigid substrate of the bending region by adopting a laser lift-off process; wherein
the first light absorbing portion is in the display region and on one side of the display region close to the bending region, and the first light absorption portion is configured to absorb light comprising a waveband of a laser light.

35. The method according to claim 34, further comprising:
forming a second light absorption portion on the first surface of the rigid substrate before forming the flexible film layer on the first surface of the rigid substrate;
or, forming a second light absorption portion on the second surface of the rigid substrate before forming the flexible film layer on the first surface of the rigid substrate;
or, forming a second light absorption portion on the second surface of the rigid substrate after forming the display function layer and before removing the rigid substrate of the bending region by adopting the laser lift-off process; wherein
the second light absorbing portion is in the bonding region and on one side of the bonding region close to the bending region, and the second light absorption portion is configured to absorb light comprising a waveband of a laser light.

36. The method according to claim 35, wherein the first light absorption portion and the second light absorption portion are formed at the same time.

37. The display apparatus according to claim 33, wherein the display substrate further comprises: a second light absorption portion in the bonding region and on one side of the bonding region close to the bending region;
wherein the second light absorption portion is on the side of the rigid substrate facing away from the flexible film layer or on the side of the rigid substrate facing the flexible film layer.

38. The display apparatus according to claim 37, wherein a material of the first light absorption portion comprises an inorganic material; and/or a material of the second light absorption portion comprises an inorganic material.
